(19) United States
(12) Patent Application Publication
(10) Pub. No.: US 2002/0031903 A1
(43) Pub. Date: Mar. 14, 2002

(54) Component mounting apparatus and method, component mounting system having the apparatus, and circuit board manufactured by the method

(76) Inventors: Hiroshi Yamauchi, Katano-shi (JP); Masanori Yasutake, Hirakata-shi (JP); Youichi Nakamura, Osaka-shi (JP); Junji Ikeda, Ikoma-shi (JP)

Correspondence Address: WENDEROTH, LIND & PONACK, L.L.P., 2033 K STREET N. W., SUITE 800, WASHINGTON, DC, 20006-1021, US

(21) Appl. No.: 09/940,583

(22) Filed: Aug. 29, 2001

(30) Foreign Application Priority Data
Aug. 29, 2000 (JP) 2000-258959

(51) Int. Cl. H01L 21/44; H01L 21/48; H01L 21/50

(52) U.S. Cl. 438/612; 438/106; 438/107

(57) ABSTRACT

A component mounting apparatus has an ultrasonic vibration generating apparatus which supplies ultrasonic vibration making a lead-free solder with no lead which is provided between an electronic component and a circuit board melted to the electronic component. The lead-free solder is melted by the ultrasonic vibration and then connects the electronic component on the circuit board. Accordingly, the ultrasonic vibration generating apparatus can heat only the lead-free solder partially, the electronic component and the circuit board can be joined without applying thermal influence to a whole of the electronic component and circuit board.

### BACKGROUND OF THE INVENTION

The present invention relates to a component mounting apparatus for connecting components by using a lead-free solder not including lead, a component mounting method executed with the component mounting apparatus, a component mounting system comprising the component mounting apparatus, and a circuit board produced by the component mounting method.

For example, when electronic components are mounted on a circuit board, the electronic components and the circuit board are generally connected by eutectic solder. Solder is used for mounting operation of the electronic components for many years because the solder is easier to get and handle, and further melts in a low temperature and has good electrical characteristic.

Recently, however, use of toxic substances are regulated from the viewpoint of environmental problems. The influence of the lead to a human body becomes problems including contamination of groundwater due to the lead dissolving from electric products which are thrown away and buried in the underground. Thus, it is desired to provide a solder with no lead.

Accordingly, development of a lead-free solder not including lead is performed briskly focusing on material-makers, and contents of research and embodiments regarding the lead-free solders having various compositions are announced.

Various kinds of lead-free solder having alloy composition such as Sn—Ag, Sn—Ag—Bi, Sn—Ag—Bi—In, Sn—Zn, and the like are developing now and announced. Some of them have mechanical characteristics and reliability similar to those of the conventional eutectic solder of Sn—Pb, but they have a problem that their melting points are higher than that of the eutectic solder of Sn—Pb as shown in FIG. 11. If a temperature of an atmosphere for the connection can be raised to match with a melting point of the lead-free solder, some of the lead-free solders can be used.

However, the higher temperature of the atmosphere may cause breakdown of the electric components. On the other hand, if a connection condition similar to that of the related art is used, the connection of the electric components to the circuit board becomes difficult from the viewpoint of a heatproof temperature of the electric component and a temperature control ability of a heating apparatus in a reflow apparatus because the lead-free solder can not melt fully and can not get good solderability to the electric components.

In the composition of the lead-free solder, although it is considered that at least one of Bi and In corresponding to low-melting point metals is added more than normal, however excessive addition of Bi and/or In causes a brittle fracture to the lead-free solder easily and a low-reliability of the circuit board. Further it is also necessary to consider that the production cost of the lead-free solder is increased because of less reserves of In. The lead-free solder alloy consisting essentially of Sn—Zn has a low production cost comparatively and a melting point close to that of the eutectic solder of Sn—Pb. However, it is difficult to store the lead-free solder alloy consisting essentially of Sn—Zn with stability in paste condition, and the principal problem is that the composition of the solder with Sn—Zn is not maintained with stability because diffusion between Zn and Cu in the circuit is active.

As above, under the present circumstances, there is no solder material satisfying all of desires such as the melting point, mechanical characteristics, production cost and the like, and being able to substitute for the eutectic solder of Sn—Pb easily.

### SUMMARY OF THE INVENTION

Accordingly, an object of the present invention is to provide a component mounting apparatus, a component mounting method executed with the component mounting apparatus, a component mounting system comprising the component mounting apparatus, and a circuit board produced by the component mounting method. In the component mounting apparatus, a lead-free solder having a melting point higher than that of the eutectic solder of Sn—Pb is used, and the component mounting apparatus can join components and an object to be mounted without applying thermal influence to the components and the object.

In accomplishing these and other aspects, according to a first aspect of the present invention, there is provided a component mounting apparatus for mounting components onto an object to be mounted, which comprises:

a component holding apparatus for holding the component;

an object holding apparatus for holding the object on which the component is mounted; and

an ultrasonic vibration generating apparatus included in the component holding apparatus for applying ultrasonic vibration to the component and making a lead-free solder with no lead melt by the ultrasonic vibration, the lead-free solder being provided between the component and the object, and joining and connecting electrically the component and the object due to a solidification after the melting of the lead-free solder.

According to a second aspect of the present invention, there is provided a component mounting system comprising:

a first component mounting apparatus for mounting a first component which endures a melting point of a lead-free solder with no lead onto a circuit board;

a second component mounting apparatus for mounting an electronic component which is susceptible to the melting point of the lead-free solder onto the circuit board on which the first component is already mounted; and

an ultrasonic vibration generating apparatus included in the second component mounting apparatus for applying ultrasonic vibration to the electronic component and making the lead-free solder melt by the ultrasonic vibration, the lead-free solder being provided between the electronic component and the circuit board, and joining and connecting electrically the electronic component and the circuit board due to a solidification after the melting of the lead-free solder.

The component mounting system may further comprises a printing apparatus arranged at a previous step of the first component mounting apparatus and for applying the lead-free solder to the circuit board; and

a reflow apparatus arranged between the first component mounting apparatus and the second component mounting apparatus, and for melting the lead-free solder and joining the first component and the circuit board.

According to a third aspect of the present invention, there is provided a component mounting method comprising:

holding a component and an object on which the component is mounted; and

applying ultrasonic vibration to the component and then making a lead-free solder with no lead melt by the ultrasonic vibration, so that the component is mounted on the object,

the lead-free solder being provided between the component and the object, and joining and connecting electrically the component and the object due to a solidification after the melting of the lead-free solder.

The component mounting method may further comprise to join a first component previously which has a better heat resistance than the component on the object before the component and the object are joined by the lead-free solder.

According to a fourth aspect of the present invention, there is provided a circuit board comprising a component joined by lead-free solder with no lead according to the component mounting method defined in the third aspect.

According to a fifth aspect of the present invention, there is provided a component mounting apparatus for mounting components onto an object to be mounted, which comprises:

a component holding apparatus for holding the component;

an object holding apparatus for holding the object on which the component is mounted; and

a lead-free solder melting apparatus included in the component holding apparatus for making a lead-free solder with no lead melt which is provided between the component and the object, and joins and connects electrically the component and the object due to a solidification after the melting of the lead-free solder.

By the above construction of the component mounting apparatus of the first aspect, the component mounting system of the second aspect, and the component mounting method of the third aspect, the ultrasonic vibration generating apparatus is comprised and joins the component and the object to melt the lead-free solder with frictional heat generated by the ultrasonic vibration of the component when the component and the object is connected with the lead-free solder. Thus only the lead-free solder can be heated partially and a whole of the component and object is not heated. Therefore the component and the object can be connected without giving thermal effects to the whole of the component and the object.

Connecting material for joining the component and object is the lead-free solder with no lead. Thus electrical characteristics of the component, mechanical characteristics of the order of that of the eutectic solder of Sn—Pb, and reliability can be ensured, and a connecting condition can be set easily.

As the lead-free solder does not include lead, mounting method for being able to avoid releasing of toxic substance to the environment can be provided.

Also, according to the component mounting method of the second aspect, after the first component having the better heat resistance is mounted onto the circuit board by the first component mounting apparatus, the ultrasonic vibration is applied to a component with bad heat resistance by the second component mounting apparatus, thereby connecting the component with bad heat resistance to the circuit board. Therefore, the component with bad heat resistance can be connected to the circuit board without applying high temperature in which the first component is received to the component with bad heat resistance. Accordingly, the component mounting system having the increased productivity and high-quality can be produced.

Further according to the circuit board of the fourth aspect, the component is mounted by using the lead-free solder in the component mounting method of the second aspect. Thus the circuit board for being able to avoid releasing of toxic substance to the environment can be provided.

Further according to the component mounting apparatus of the fifth aspect, the lead-free solder melting apparatus is comprised and melts the lead-free solder with heat generated by the lead-free solder melting apparatus so as to join the component and the object when the component and the object is connected with the lead-free solder. Thus only the lead-free solder can be heated partially and a whole of the component and object is not heated. Therefore the component and the object can be connected without giving thermal effects to the whole of the component and the object.

Connecting material for joining the component and object is the lead-free solder with no lead. Thus electrical characteristics of the component, mechanical characteristics of the order of that of the eutectic solder of Sn—Pb, and reliability can be ensured, and a connecting condition can be set easily.

As the lead-free solder does not include lead, mounting method for being able to avoid releasing of toxic substance to the environment can be provided.

### BRIEF DESCRIPTION OF THE DRAWINGS

These and other aspects and features of the present invention will become clear from the following description taken in conjunction with the preferred embodiments thereof with reference to the accompanying drawings, in which:

FIG. 1 is a diagram of a part of an ultrasonic vibration generating apparatus in a component mounting apparatus of an embodiment of the present invention, showing a connecting condition of an electronic component and a circuit board;

FIG. 2 is a perspective view of a head part, comprised in the component mounting apparatus of the embodiment, having the ultrasonic vibration generating apparatus of FIG. 1;

FIG. 3 is a perspective view of the component mounting apparatus of the embodiment;

FIG. 4 is a graph showing a change in temperature at a connection material when the electronic component and the circuit board are connected with the component mounting apparatus of the embodiment;

FIG. 5 is a diagram showing a conventional connecting condition of the electronic component and circuit board;

FIG. 6 is a diagram showing a conventional connecting condition of the electronic component and circuit board;

FIG. 7 is a diagram showing a connecting condition of the electronic component mounted on the circuit board by the component mounting apparatus of the embodiment;

FIG. 8 is a diagram showing an example of construction of a component mounting system including the component mounting apparatus of the embodiment;

FIG. 9 is a diagram showing a mounting condition in which a first component is mounted on the circuit board with a first component mounting apparatus and a reflow apparatus in the component mounting system of FIG. 8;

FIG. 10 is a diagram showing a mounting condition in which an electronic component is mounted with a second component mounting apparatus in the component mounting system of FIG. 8 in addition to the mounting condition of FIG. 9; and

FIG. 11 is a graph showing a change in temperature at a connection material when an electronic component and a circuit board are connected with a conventional component mounting apparatus.

### BEST MODE FOR CARRYING OUT THE INVENTION

A component mounting apparatus, a component mounting method executed with the component mounting apparatus, a component mounting system comprising the component mounting apparatus, and a circuit board made by the component mounting method which are embodiments of the present invention will be described hereinbelow with reference to the drawings. It is to be noted that like parts are designated by like reference numerals throughout the drawings. In this embodiment, an electronic component is taken as an example of a component and a circuit board is taken as an example of an object to be mounted, however the component and the object are not limited to those. In this Specification and Claim, the object means a material goods forming a circuit, for example, a circuit board such as a resin board, a paper-phenol board, a ceramic board, a glass-epoxy board, a film board, and the like; a circuit board such as a single-layer board or a multilayer board, or the like; a component; a cabinet; or flame, etc.

Also, in this embodiment, a lead-free solder as a connection material is used in order to connect between electrodes of the electronic component and electrode portions of the circuit board.

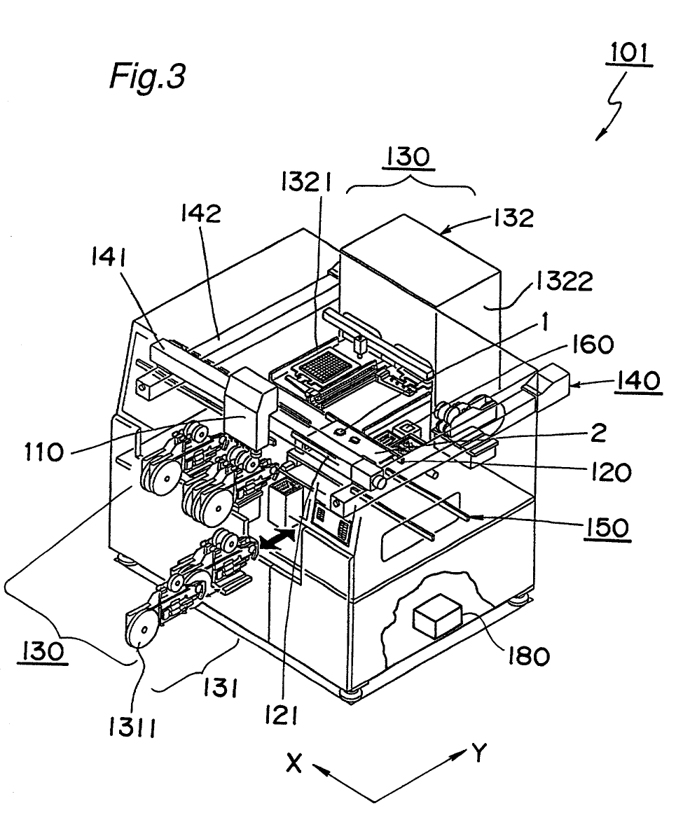

As shown in FIG. 3, a component mounting apparatus 101 of the present embodiment comprises roughly a component holding device 110, an object to be mounted holding device 120, a component feeding device 130, a moving device 140, a board transferring device 150, a control device 180, and a component recognition device 160. The component holding device 110 and the object holding device 120 are a basic constitution portion of the component mounting apparatus 101.

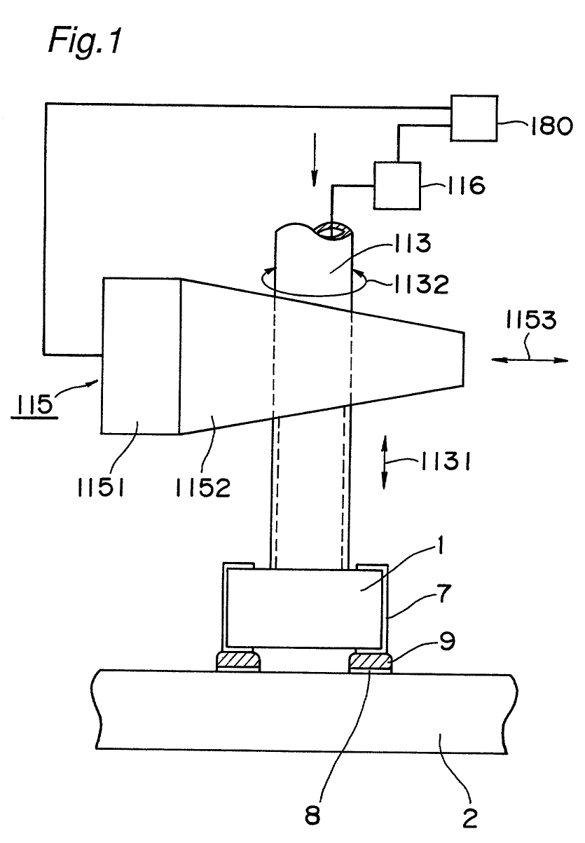

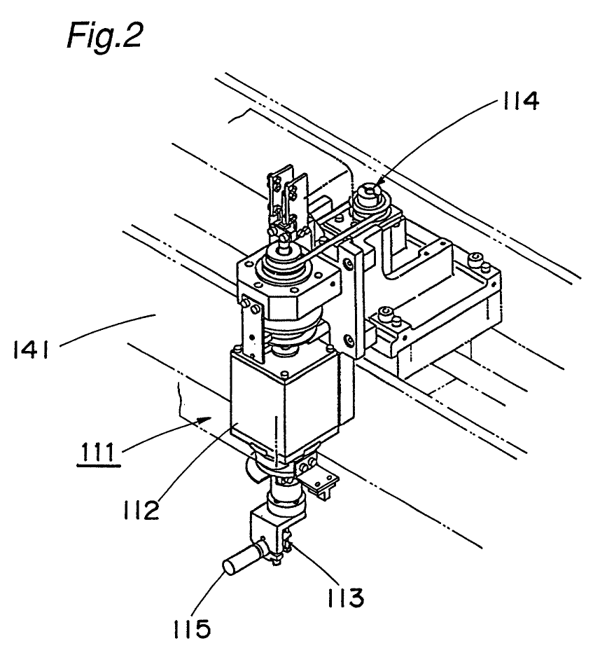

The component holding device 110 is a device for holding an electronic component 1 as one example of the component from the component feeding device 130 and mounting the held electronic component 1 onto a circuit board 2 as one example of the object to be mounted held by the object holding device 120. The component holding device 110 has four head parts 111 shown in FIGS. 2 and 1 in the embodiment, and is installed to the moving device 140. The moving device 140 has an X-mechanism extending along an X-direction and a Y-mechanism extending along a Y-direction which have ball-screw mechanisms respectively, and move the component holding device 110 to the X and Y directions.

In FIG. 2, only one set of the head part 111 is shown.

Each head part 111 of the component holding device 110 has one nozzle 113 for sucking and holding the electronic component 1 as an example of component holding members, an ascent/descent part 112, a rotation driving part 114, an ultrasonic vibration generating device 115, and a suction device 116.

The ascent/descent part 112 is a device for moving the nozzle 113 up and down along an axial direction thereof in order to hold and mount the electronic component 1. When the electronic component 1 is held from the component feeding device 130 and mounted onto the circuit board 2, the ascent/descent part 112 can control pressing force applying to the electronic component 1 held by the nozzle 113 in accordance with a controlled current fed to the ascent/descent part 112. The controlling of the current fed to the ascent/descent part 112 is performed by the control device 180.

The rotation driving part 114 is a device for rotating the nozzle 113 to a circumferential direction 1132 thereof in order to correct a held attitude of the electronic component 1 held by the nozzle 113. The suction device 116 is a device connected to the nozzle 113 and for vacuuming a portion within the nozzle in order to suck and hold the electronic component with the nozzle 113. The rotation driving part 114 and the suction device 116 are controlled by the control device 180.

The ultrasonic vibration generating device 115 is one of the characteristic constitutions in the component mounting apparatus 101 of the embodiment, and is attached to the nozzle 113. The ultrasonic vibration generating device 115 is a device for vibrating the nozzle 113 ultrasonically along an almost orthogonal direction 1153, and has piezoelectric elements 1151 and an ultrasonic horn 1152. The above orthogonal direction 1153 is a direction orthogonal to the axial direction 1131. The ultrasonic vibration generating device 115 is controlled in operation by the control device 180. Also, the ultrasonic vibration generating device 115 corresponds to one example of lead-free solder melting apparatuses.

The piezoelectric elements 1151 are attached at one end of the ultrasonic horn 1152, and generates micro-vibration according to feeding and shutting off current. Other end of the ultrasonic horn 1152 is fixed to the nozzle 113. The ultrasonic horn 1152 amplifies the micro-vibration generated at the piezoelectric elements 1151 and vibrates the nozzle 113 along the almost orthogonal direction 1153 as above. As described below, when the electronic component 1 is sucked by the nozzle 113, according to the ultrasonic vibration of the nozzle 113, the electronic component is vibrated with ultrasonic.

When the electronic component 1 is mounted onto the circuit board 2, electrodes 7 of the electronic component 1 and lands 8 corresponding to electrode portions of the circuit board 2 are arranged face-to-face. Also, melt connection material 9 for joining the electronic component 1 and the circuit board 2 is provided previously at least one of the electrodes 7 and the lands 8 between the electrodes 7 and the lands 8. The melt connection material 9 can be provided by applying the material 9 to the electric component 1 or the circuit board 2 and then melting and solidifying, or by a plating process. Further, without melting and solidifying the material 9, a melt connection material 9 in a sheet shape may be inserted between the electronic component 1 and the circuit board 2 by using liquid with viscosity such as flux.

In the embodiment, the melt connection material 9 is a lead-free solder alloy consisting essentially of Sn—Ag—Bi of which the melting point is about 216° C.

When the electronic component 1 is mounted and then connected onto the circuit board 2 in a condition that the melt connection material 9 of the lead-free solder is provided between the electronic component 1 and the circuit board 2, the ultrasonic vibration generating device 115 works. On the other hand, the circuit board 2 is fixed by the object holding device 120. Accordingly, the electronic component 1 held by the nozzle 113 is vibrated ultrasonically via the nozzle 113, and then friction occurs therefore frictional heating is generated at between the melt connection material 9 and the lands 8 when the melt connection material 9 is provided at the electrodes 7 of the electronic component 1, or at between the melt connection material 9 and the electrodes 7 when the melt connection material 9 is provided at the lands 8. Due to the frictional heating, the melt connection material 9 is melted at least at a contact portion between the lands 8 or the electrodes 7 and the melt connection material 9, and then the electrodes 7 and the lands 8 are connected when the melt connection material 9 is solidify.

Accordingly, the ultrasonic vibration generated by the ultrasonic vibration generating device 115 is a vibration with a vibration value such that the melt connection material 9 of the lead-free solder can be melted. Concretely, the vibration is, for example an amplitude of 10 μm in an ultrasonic frequency of 20 kHz, an amplitude of 0.1 μm in an ultrasonic frequency of 350 kHz, or the like. Since a connecting area of the melt connection material 9 is larger than that of a bump bonding apparatus for forming bumps and a flip-chip bonding apparatus, it is necessary for the ultrasonic vibration generating device 115 to generate more energy than that of the bump bonding apparatus and the flip-chip bonding apparatus.

The board transferring device 150 is a device having a loader part for incoming the circuit board 2 from a previous process to the component mounting apparatus 101 and an unloader part for serving the circuit board 2 from the component mounting apparatus 101 to a next process. The board transferring device 150 has a transfer belt supporting or holding the circuit board 2 for the transferring and a transfer belt driving device for driving the belt, etc. The board transferring device 150 is arranged along the X-direction in the embodiment. Thus the circuit board 2 is transferred along the X-direction.

The object holding device 120 is arranged so as to be able to connect to the board transferring device 150 at between the loader part and the unloader part of the board transferring device 150, and has a table 121 for holding and fixing the circuit board 2 income from the previous process. Also, the object holding device 120 can move the table 121 to the Y-direction in order to mount the electronic component 1 by the component holding device 110. Further, the table 121 has a heater, connected to the control device 180, therein for heating the circuit board 2 as needed. The heater can heat the circuit board 2 previously to control a temperature of the circuit board 2 according to a condition of connection so that the melt connection material 9 can be melted easily with the ultrasonic vibration.

The component feeding device 130 is a device for feeding the electronic components 1 mounted onto the circuit board 2, and has a reel-type feeding device 131 and a tray-type feeding device 132 in the embodiment. The reel-type feeding device 131 has a reel 1311 which winds a tape carrying the electronic components 1, and feeds the electronic components 1 by reeling out the tape from the reel 1311. In the embodiment, as shown in figure, there are plural reel-type feeding devices 131. The tray-type feeding device 132 stores trays 1321 which are shaped like plates and support the electronic components 1 in respective partitions divided in a lattice within a tray storage part 1322, and is a device for feeding a necessary electronic component 1 for mounting by pulling a tray 1321 supporting the necessary electronic component 1 out from the tray storage part 1322.

The component recognition device 160 is a device for picking up a held attitude of the electronic component 1 which is being held by the nozzle 113 of the component holding device 110, and sending image pickup information thereof to the control device 180. The component recognition device 160 is arranged at a position within a passage area of the component holding device 110 where the component recognition device 160 can pickup the image of the electronic component 1 from a position under the electronic component 1. The control device 180 decides a displacement amount between the held attitude of the electronic component 1 held with the nozzle 113 and a normal held attitude on a basis of the image pickup information. Then the control device 180 controls moving amounts in the X- and Y-directions of the moving device 140 and a rotation amount of the nozzle 113 by the rotation driving part 114 of the component holding device 110 based on the decided displacement amount so that the electronic component 1 can be mounted correctly onto the circuit board 2.

Operation of the component mounting apparatus 101 constituted as above, that is a component mounting method will be described hereinbelow. The component mounting method is controlled in operation by the control device 180 and then executed.

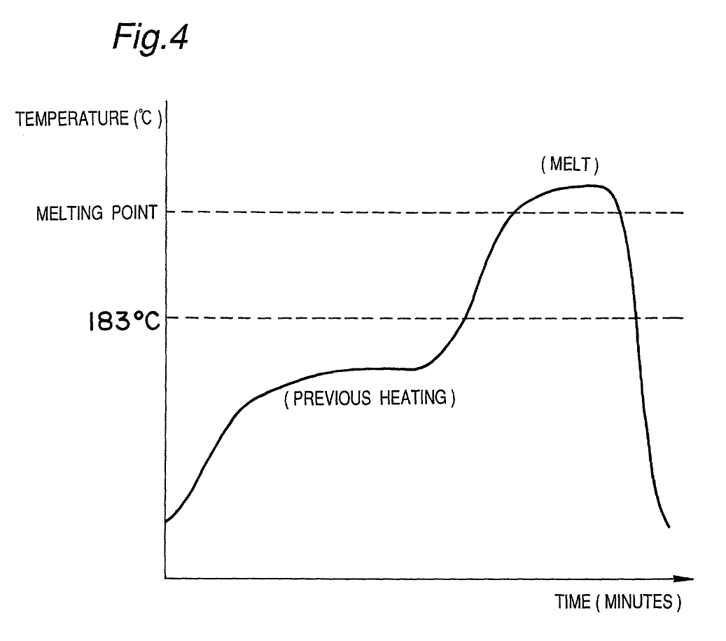

The circuit board 2 is transferred to the component mounting apparatus 101 by the board transferring device 150 and then is positioned and fixed by the table 121 of the object holding device 120. It is preferable that the positioned circuit board 2 is heated previously to a temperature into which the melt connection material 9 is not melted as shown in FIG. 4 by the heater in the table 121 before mounting of the electronic component 1 because the melt connection material 9 can be melted in a short time. Of course, the melt connection material 9 may be melted by only the ultrasonic vibration of the ultrasonic vibration generating device 115.

Next, the moving device 140 works and then makes the component holding device 110 move toward the component feeding device 130, whereby the electronic component 1 is sucked and held by the nozzle 113. As described above, in the embodiment, there are four head parts 111 and four nozzles 113. Thus, basically, each nozzle 113 is sucked the electronic component 1 respectively. After the sucking operation, the moving device 140 works again and then makes the component holding device 110 locate at above the component recognition device 160. Then the component recognition device 160 picks up the held attitudes of the respective electronic components 1 held by the nozzles 113, and sends respective pieces of the image pickup information to the control device 180. The control device 180 determines each displacement amount of the X-direction, the Y-direction, and a θ-direction which is the circumferential direction of the nozzle 113 for respective electronic components 1 on a basis of pieces of image pickup information of the respective electronic components 1. Each displacement amount in the respective electronic components 1 is an amount of difference between a mounting position registered previously in the control device 180 for mounting the electronic component 1 onto the circuit board 2 and a position of the held attitude of the electronic component 1.

Then, when electronic components 1 held by the respective nozzles 113 are mounted onto the circuit board 2, the control device 180 controls each operation of the moving device 140 and the rotation driving part 114 according to the determined displacement amounts for the respective electronic components 1 held by the nozzles 113, and then positions the component holding device 110 above the circuit board 2. After positioning each nozzle 113 in turn, the control device 180 makes the positioned nozzles 113 lower by the ascent/descent parts 112 corresponding to the positioned nozzles 113 respectively, thereby locating the electronic components 1 at the mounting positions respectively on the circuit board 2.

In the embodiment, the control device 180 determines that the electronic component 1 comes into contact with the circuit board 2 and a predetermined load is applied to the electronic component 1 on a basis of the feeding current to the ascent/descent part 112. Then the control device 180 makes the ultrasonic vibration generating device 115 work simultaneously when the applying the predetermined load is started, thereby applying the ultrasonic vibration to the nozzle 113. The predetermined load means a load which makes the melt connection material 9 generate the frictional heating not less than a melting point of the melt connection material 9.

Due to the ultrasonic vibration and the pressurization to the electronic component 1 of the nozzle 113, the electronic component 1 held by the nozzle 113 is vibrated and a temperature of the melt connection material 9 is risen to the melting point thereof and then melted am shown in FIG. 4.

After the melt, the application of the ultrasonic vibration is over. Thus the electronic component 1 and the circuit board 2 are connected to each other by the solidification of the melt connection material 9 due to a natural or forced-cooling. The forced-cooling by blowing a gas or the like is preferable because of reduction of a cooling time of the melt connection material 9.

As the embodiment, the melt connection material 9 can be heated directly because of the application of the ultrasonic vibration to the electronic component 1. Thus, even when the melt connection material having a higher melting point such as the lead-free solder, etc. than that of the conventional eutectic solder and the component with bad heat resistance are used, the junction with high reliability can be attained with the characteristic of the electronic component 1 maintained.

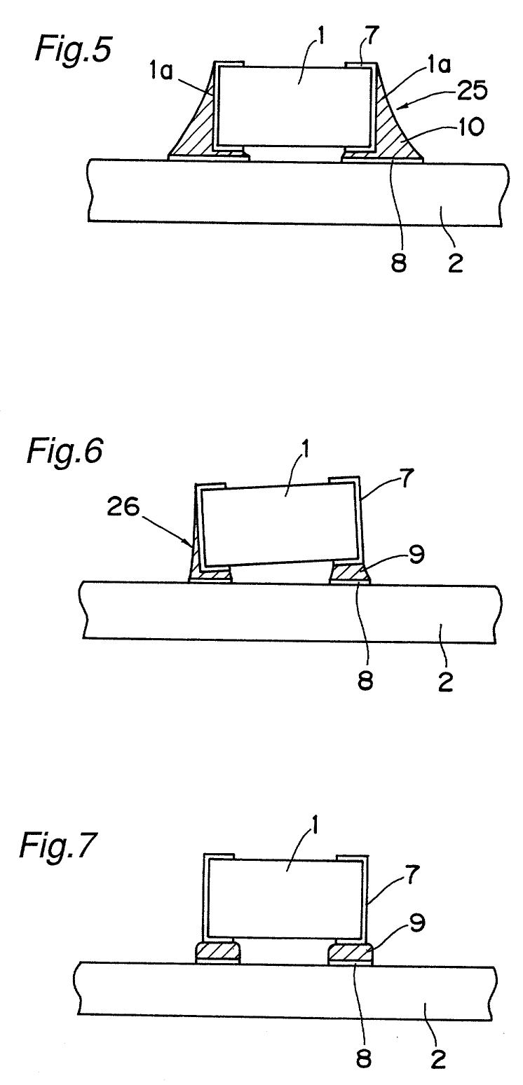

Each of FIGS. 5-7 shows a portion of the electrode in detail with the electronic component joined. FIGS. 5 and 6 show the portions formed by the conventional mounting method, and FIG. 7 shows the portion formed by the mounting method of the embodiment.

In the conventional mounting method, fillets 25 of the eutectic solder 10 are formed at end faces 1a in order to ensure a junction strength of the electronic component 1. However it becomes necessary to mount the electronic components with a narrow pitch in accordance with the progression of the miniaturization of the electronic components. Therefore, a mounting method not using the fillet has come to use as shown in FIG. 6. In this method, if there is a sufficient amount of the eutectic solder 10 between the electrode 7 and the land 8, the junction strength of the electronic component 1 can be ensured. However, when wicking portions 26 of the eutectic solder 10 are formed along the end faces 1a of the electronic component 1 by capillary action, the amount of the eutectic solder 10 between the electrode 7 and the land 8 is decreased. Thus it becomes difficult to ensure the junction strength of the electronic component 1. By the way, a condition of FIG. 5 does not show a mounting condition with narrow pitch. Therefore a sufficient amount of the eutectic solder 10 can be used, the junction strength can be ensured by the fillet 25, even if there are a little eutectic solder 10 between the electrode 7 and the land 8.

On the other hand, in the mounting method of the embodiment based on FIG. 7, the melt connection material 9 can be heated directly and partially as mentioned above. Therefore, at least a contact surface portion between the electrode 7 or land 8 and the melt connection material 9 can be melted. Accordingly, since there is no case that is the wicking portions 26 shown in FIG. 6 are formed, a mounting area can be reduced and a thickness of the melt connection material 9 can be ensured fully. Therefore, sufficient junction strength can be ensured.

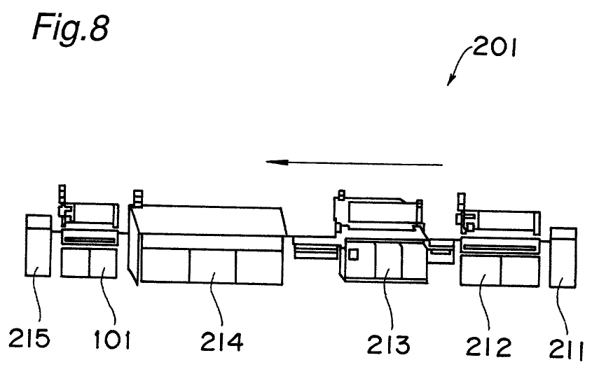

Next, by comprising the component mounting apparatus 101 of the embodiment mentioned above, one example of a circuit board mounting system 201 in FIG. 8 can be constructed.

The circuit board mounting system 201 has a storage cabinet for feeding circuit board 211, a printing press of connection material 212, a first component mounting apparatus 213, a reflow apparatus 214, the component mounting apparatus 101 as a second component mounting apparatus, and a storage cabinet 215. Those units 211-214, 101, and 215 are arranged from the right in FIG. 8 in this turn. Also, the circuit board 2 is transferred from the right to the left in FIG. 8.

The circuit board mounting system 201 having the is 4 above construction operates as follows.

The circuit board 2 is sent out from the storage cabinet for feeding circuit board 211. A melt connection material, for example, the melt connection material 9 of the lead-free solder described above is printed on the circuit board 2 by the printing press of connection material 212. Next, only a first component 221 is mounted on the circuit board 2 by the first component mounting apparatus 213. The first component 221 is a heat resistance electronic component in which problems do not arise even if the heat resistance electronic component is heated to a temperature which is not less than the melting point of the melt connection material 9 and is higher than that of the conventional eutectic solder including lead. That is to say, the first component mounting apparatus 213 does not mount the component with bad heat resistance producing the problems when the temperature which is not less than the melting point of the melt connection material 9 at the reflow apparatus 214 of the next process is applied to the bad heat resistance component.

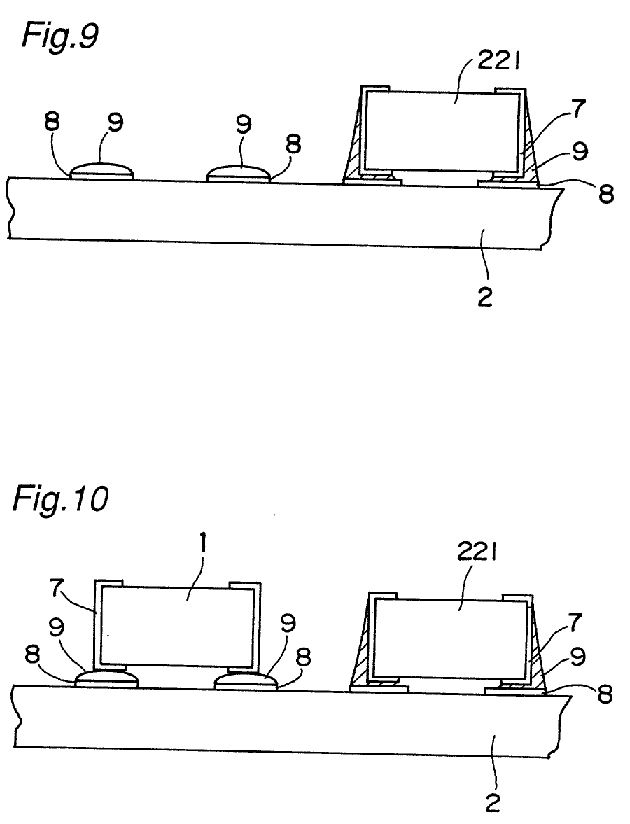

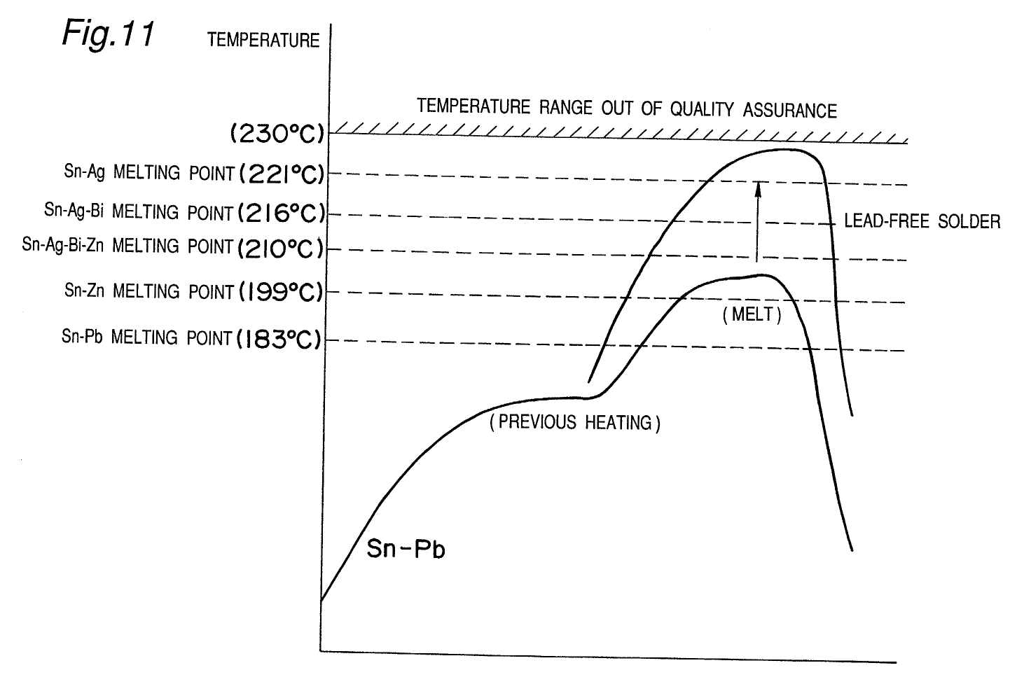

Next, the reflow apparatus 214 melts the melt connection material 9 and joins the first component and the circuit board 2 electrically and physically to each other as shown in FIG. 9. In this situation, the melt connection material 9 applied on the land 8 on which the bad heat resistance component is not mounted yet of the circuit board 2 has been melted and solidified.

Next, the circuit board 2 on which the first component is mounted as above is transferred to the above component mounting apparatus 101. According to the operation as above, the component mounting apparatus 101 puts the electronic component 1 as the bad heat resistance component at a predetermined mounting position on the circuit board 2, and then presses the electronic component 1 and applies the ultrasonic vibration to the electronic component 1. Therefore, at least a contact portion between the melt connection material 9 in the solidified condition on the land 8 and the electrode 7 of the electronic component 1 is melted by the frictional heating produced by the ultrasonic vibration of the electronic component 1 and then solidified. Thus, as shown in FIG. 10, the land 8 of the circuit board 2 and the electrode 7 of the electronic component 1 as the bad heat resistance component are joined electrically and physically to each other with the melt connection material 9. According to the above operation, the electronic components 1 corresponding to the bad heat resistance components are mounted onto the circuit board 2.

After mounting all of the electronic components 1, the circuit board 2 is stored within the storage cabinet 215 and then transferred to the next process.

In this system 201, the melt connection material 9 is applied at one time. Therefore, since it is not necessary to provide the melt connection material 9 corresponding to each of the first component 221 and electronic component 1, steady quality can be ensured without loss of productivity.

Also, the first component mounting apparatus 213 does not mount the electronic component 1 producing the problems at the temperature higher than the melting point of the conventional eutectic solder onto the circuit board 2, and the component mounting apparatus 101 can heat only the melt connection material 9 directly and partially which joins the electronic component 1 to the circuit board 2. Therefore, even when the melt connection material having a higher melting point such as the lead-free solder, etc. than that of the conventional eutectic solder and the component with bad heat resistance are used, the junction with high reliability can be attained with the characteristic of the electronic component 1 maintained.

Even if the melt connection material 9 is conductive paste other than the solder, the conductive paste can attain effects similar to the above mentioned effects.

In the above embodiment, as the method for melting the melt connection material 9, the frictional heating is produced at the melt connection material 9 by vibrating ultrasonically the electronic component 1 held with the nozzle 113. However the melting method of the melt connection material 9 is not limited to the above method. For example, a laser light radiation apparatus as one example of lead-free solder melting apparatuses may be used. In this constitution, the lead-free solder as the melt connection material 9 may be melted by the laser light radiated to the lead-free solder from the laser light radiation apparatus.

Although the present invention has been fully described in connection with the preferred embodiments thereof with reference to the accompanying drawings, it is to be noted that various changes and modifications are apparent to those skilled in the art. Such changes and modifications are to be understood as included within the scope of the present invention as defined by the appended claims unless they depart therefrom.

What is claimed is:

1. A component mounting apparatus for mounting components onto an object to be mounted, which comprises:
a component holding apparatus for holding the component;
an object holding apparatus for holding the object on which the component is mounted; and
an ultrasonic vibration generating apparatus included in the component holding apparatus for applying ultrasonic vibration to the component and making a lead-free solder with no lead melt by the ultrasonic vibration, the lead-free solder being provided between the component and the object, and joining and connecting electrically the component and the object due to a solidification after the melting of the lead-free solder.

2. A component mounting system comprising:
a first component mounting apparatus for mounting a first component which endures a melting point of a lead-free solder with no lead onto a circuit board;
a second component mounting apparatus for mounting an electronic component which is susceptible to the melting point of the lead-free solder onto the circuit board on which the first component is already mounted; and
an ultrasonic vibration generating apparatus included in the second component mounting apparatus for applying ultrasonic vibration to the electronic component and making the lead-free solder melt by the ultrasonic vibration, the lead-free solder being provided between the electronic component and the circuit board, and joining and connecting electrically the electronic component and the circuit board due to a solidification after the melting of the lead-free solder.

3. The component mounting system according to claim 2, further comprising:
a printing apparatus arranged at a previous step of the first component mounting apparatus and for applying the lead-free solder to the circuit board; and
a reflow apparatus arranged between the first component mounting apparatus and the second component mounting apparatus, and for melting the lead-free solder and joining the first component and the circuit board.

4. A component mounting method comprising:
holding a component and an object on which the component is mounted; and
applying ultrasonic vibration to the component and then making a lead-free solder with no lead melt by the ultrasonic vibration, so that the component is mounted on the object,
the lead-free solder being provided between the component and the object, and joining and connecting electrically the component and the object due to a solidification after the melting of the lead-free solder.

5. The component mounting method according to claim 4, further comprising:
before the component and the object are joined by the lead-free solder, joining a first component previously which has a better heat resistance than the component on the object.

6. A circuit board comprising a component joined by a lead-free solder with no lead on a basis of the component mounting method defined in claim 4.

7. A circuit board comprising a component joined by a lead-free solder with no lead on a basis of the component mounting method defined in claim 5.

8. A component mounting apparatus for mounting components onto an object to be mounted, which comprises:
a component holding apparatus for holding the component;
an object holding apparatus for holding the object on which the component is mounted; and
a lead-free solder melting apparatus included in the component holding apparatus for making a lead-free solder with no lead melt which is provided between the component and the object, and joins and connects electrically the component and the object due to a solidification after the melting of the lead-free solder.
